(19) United States
(12) Patent Application Publication
(10) Pub. No.: US 2021/0296356 A1
(43) Pub. Date: Sep. 23, 2021

(54) SEMICONDUCTOR DEVICE AND SEMICONDUCTOR DEVICE MANUFACTURING METHOD

(71) Applicant: Kioxia Corporation, Tokyo (JP)

(72) Inventor: Ryo KANAI, Yokkaichi (JP)

(73) Assignee: Kioxia Corporation, Tokyo (JP)

(21) Appl. No.: 17/018,857

(22) Filed: Sep. 11, 2020

(30) Foreign Application Priority Data
Mar. 17, 2020 (JP) 2020-046767

(51) Int. Cl. H01L 27/11582; H01L 27/11556; G11C 5/02; G11C 5/06

(52) U.S. Cl. CPC H01L 27/11582; G11C 5/06; G11C 5/025; H01L 27/11556

(57) ABSTRACT

A semiconductor device according to one embodiment includes a stacked body including first films and second films that are stacked alternatively one on another, the stacked body having a stair shape at end portions thereof; a thick film portion thicker than the second films within the stacked body and provided on an upper surface of a first step of the stair shape; a separating portion provided on a side face between the first step and a second step one-step above the first step, the separating portion separating the thick film portion from the side surface; a third film provided to cover the stacked body and the thick film portion; and an electrically conductive column portion penetrating through the third film to be in contact with the thick film portion.

### CROSS-REFERENCE TO RELATED APPLICATIONS

This application is based upon and claims the benefit of priority from Japanese Patent Application No. 2020-046767, filed on Mar. 17, 2020; the entire contents of which are incorporated herein by reference.

### FIELD

Embodiments of the present disclosure relate to a semiconductor device and a semiconductor device manufacturing method.

### BACKGROUND

Some semiconductor storage devices having a three-dimensional structure have a stacked body in which electrically conductive layers and insulating layers are stacked alternately one on the other. In the stacked body, columnar channels are formed to penetrate through the stacked body, and memory cells are formed in intersecting portions of the electrically conductive layers and the channels. On the other hand, edge portions of the stacked body are formed into a stair shape so that the electrically conductive layers are exposed; contacts are provided onto corresponding electrically conductive layers; and thus each of the electrically conductive layers is electrically connected to outside of the stacked body.

### BRIEF DESCRIPTION OF DRAWINGS

FIGS. 1A through 1F are schematic representations illustrating cross-sections of a semiconductor device after corresponding process steps in a semiconductor device manufacturing method according to one embodiment;

FIGS. 2G through 2L are schematic representations illustrating cross-sections of the semiconductor device after corresponding process steps in the semiconductor device manufacturing method according to the embodiment, continued from FIG. 1F.

FIGS. 3A through 3F are schematic representations illustrating cross-sections of a semiconductor device after corresponding process steps in a semiconductor device manufacturing method according to modification 1 of the embodiment;

FIGS. 4G through 4I are schematic representations illustrating cross-sections of the semiconductor device after corresponding process steps in the semiconductor device manufacturing method according to modification 1 of the embodiment, continued from FIG. 3F; and

FIGS. 5A through 5D are schematic representations illustrating cross-sections of a semiconductor device after corresponding process steps in a semiconductor device manufacturing method according to modification 2 of the embodiment.

### DETAILED DESCRIPTION

For example, in a semiconductor storage device having a stacked body in which electrical conductive layers and insulating layers are stacked alternatively one on the other, the number stacking of the electrically conductive layers and the insulating layers tends to be increased, in order to increase memory capacity. Because the stacked body becomes higher as the stacking number is increasing, a contact hole becomes longer which is formed for an electrically conductive layer positioned at a lower part of the stacked body, and thus a time required to form such a contact hole becomes longer. In this situation, after another electrically conductive layer at an upper part of the stacked body is exposed at a bottom of a corresponding contact hole, the electrically conductive layer is exposed to an etching atmosphere for a relatively long time. In a worst case scenario, the contact hole may penetrates through the electrically conductive layer, which results in electrical short between vertically adjacent electrically conductive layers after the contacts are formed.

One embodiment of the present disclosure provides a semiconductor device including the stacked body of which edge portion is formed into a stair shape, wherein defects of the contact can be reduced.

A semiconductor device according to one embodiment includes a stacked body including first films and second films that are stacked alternatively one on another, the stacked body having a stair shape at end portions thereof; a thick film portion thicker than the second films within the stacked body and provided on an upper surface of a first step of the stair shape; a separating portion provided on a side face between the first step and a second step one-step above the first step, the separating portion separating the thick film portion from the side surface; a third film provided to cover the stacked body and the thick film portion; and an electrically conductive column portion penetrating through the third film to be in contact with the thick film portion.

Non-limiting, exemplary embodiments of the present invention will now be described with reference to the accompanying drawings. In the drawings, the same or corresponding reference marks are given to the same or corresponding members or components, and redundant explanations will be omitted. It is to be noted that the drawings are illustrative of the invention, and there is no intention to indicate scale or relative proportions among the members or components, or between thicknesses of various layers. Therefore, the specific thickness or size should be determined by a person having ordinary skill in the art in view of the following non-limiting embodiments.

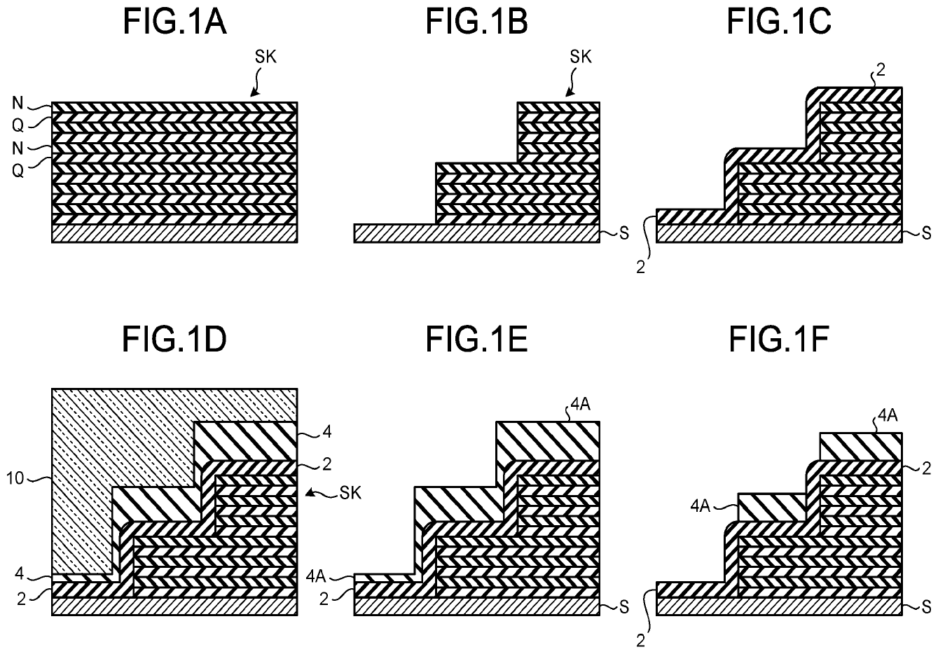

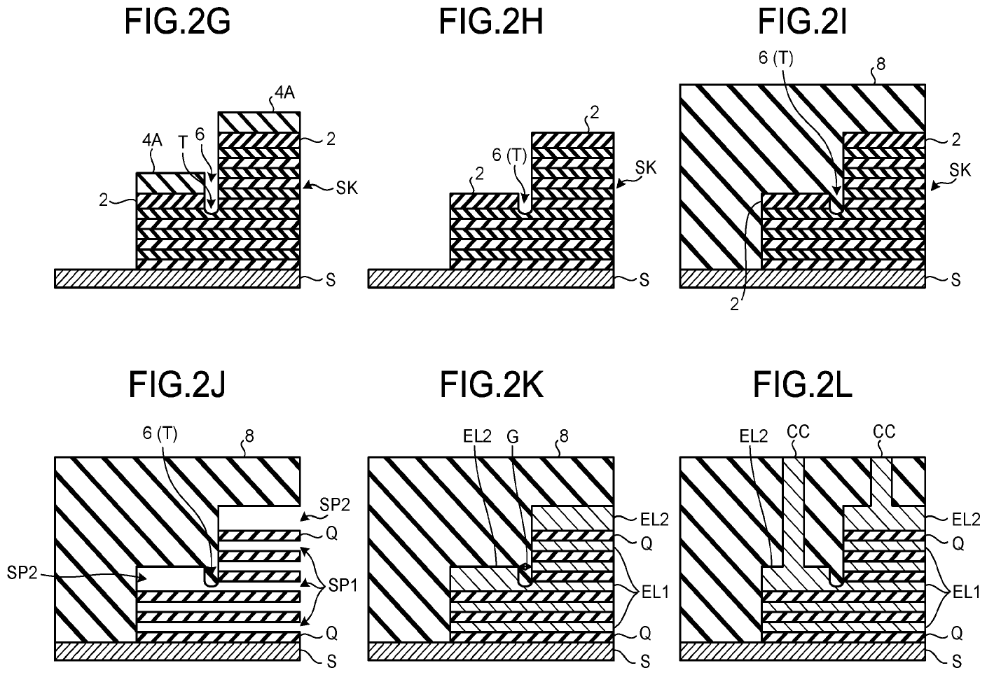

First, referring to FIGS. 1A through 2L, explanation is made on a manufacturing method of a semiconductor device according to one embodiment. FIGS. 1A through 2L are schematic representations each illustrating a cross-section of a semiconductor device after corresponding main steps among a series of process steps are performed in the manufacturing method according to this embodiment.

Referring to FIG. 1A, a stacked body SK is formed on substrate S. In the stacked body SK, silicon oxide (SiOx) layers Q and silicon nitride (SiN) layers N are stacked alternately one on the other. Each SiOx layer Q has approximately a same thickness, and each SiN layer N also has approximately a same thickness. The silicon nitride layers N are removed later, and removed spaces are filled, for example, with metal such as tungsten (W) and the like, which then turn out to be electrically conductive layers. These electrically conductive layers function as word lines to corresponding memory cells formed in semiconductor pillars that are provided to penetrate through stacked body SK.

Next, as illustrated in FIG. 1B, the stacked body SK is etched so that an edge portion thereof is formed into a stair shape. As illustrated, the SiN layers N are exposed as an upper surface (or a tread) of each step of the stairs formed by this etching. Note that, in FIG. 1B, the SiN layers N are exposed every three levels, but each of the SiN layers N is exposed as the upper surface of each step of the stairs. Specifically, although not illustrated, such a stair shape is formed in three edge portions of the stacked body SK. Another SiN layer N, for example, at the center of three SiN layers N of each step is exposed as an upper surface of another step of the stairs formed in another edge portion; and yet another SiN layer N at the lowest of the three SiN layers is exposed as yet another upper surface of yet another step of the stairs formed in yet another edge portion. Additionally, although only two steps are illustrated in FIG. 1B, the number of the steps depends on the number of SiN layers N and the SiOx layers Q in the stacked body SK. The number of the steps may be, for example, some to ten. Such a stair shape may be formed using a three-dimensional etching mask formed on the upper surface of stacked body SK, for example, by an imprint lithography method.

Next, as illustrated in FIG. 1C, a SiN film 2 is deposited on the exposed SiN layer N and on a side face (a rise) of each step of the stacked body SK. This SiN film 2 may be deposited to be conformal to an underlying layer. Namely, the SiN film 2 is formed in parallel with the SiN layer N exposed as the upper surface of each step of the stacked body SK, and has a uniform thickness. Additionally, the SiN film 2 is also approximately in parallel with the side face of each step of the stacked body SK, and has a uniform thickness.

Subsequently, a resist film 4 is applied to cover the SiN film 2, and, as illustrated in FIG. 1D, a template 10 is pressed onto this resist film 4. The template 10 has a recess shape with the multistage steps corresponding to the stair shape of the stacked body SK. When UV light is irradiated through the template 10 to the resist film 4 while the template 10 is pressed onto the resist film 4, the resist film 4 is hardened, and, as illustrated in FIG. 1E, a resist film 4A (resist pattern) of stair shape is obtained.

Next, an ashing process, for example, is performed on the resist film 4A. The ashing process is performed so that the resist film 4A is isotropically shrunk, and, as illustrated in FIG. 1F, while the resist film 4A remains on the upper surface of each step, the resist film 4A is removed in the upper surface of substrate S and the side face of each step.

Then, the SiN film 2 on the side face of each step is removed by, for example, wet etching, using as a mask the resist film 4A that remains on the upper surface of each step, as illustrated in FIG. 2G. With this, the side face of each step of the stacked body SK of stair shape is exposed. Here, a groove 6 is formed between the SiN film 2 on the upper surface of each step and the side face of the other step adjacently above. Moreover, a trench T is formed in the SiN layer N exposed in the bottom of groove 6. The trench T of the SiN layer N is formed when the SiN film 2 on the side face of each step is removed. Therefore, for example, etching time and the like is adjusted so that the SiN layer N is not completely removed when the SiN film 2 is removed, which allows the trench T to be formed in the SiN layer N. Functions of the trench T or effects exerted by the trench T are explained later.

Subsequently, as illustrated in FIG. 2H, the resist film 4A remaining on each step is removed by, for example, ashing. Thereby, the SiN film 2 becomes exposed on the upper surface of each step. Next, a SiOx film 8 is formed, for example, to cover such a structure (FIG. 2I). The SiOx film 8 may be formed by a plasma chemical vapor deposition (CVD) method using, for example, tetraethoxysilane (TEOS) as a raw material. Thereby, the above-mentioned groove 6 and trench T are filled with SiOx.

Then, as illustrated in FIG. 2J, the SiN layers N are removed through through-holes or slits (not illustrated) formed in a central portion of the stacked body SK so as to penetrate through the stacked body SK, and thus spaces SP1 are formed. At this time, the SiN film 2 remaining on the upper surface of each step is also removed. Therefore, spaces SP2 having a height L2 higher than a height L1 of space SP1 are formed in the upper part of each step.

Then, the spaces SP1 and SP2 are filled with metal such as tungsten (W) by an atomic layer deposition (ALD) method and the like, as illustrated in FIG. 2K. Thereby, electrically conductive layers EL1 corresponding to spaces SP1 and electrically conductive layers EL2 corresponding to the spaces SP2 are obtained. Here, the electrically conductive layers EL2 are formed as a single body with corresponding ones of the electrically conductive layers EL1 extending from the inside of the stacked body SK, and it is formed as electrically conductive layer EL1. Additionally, the electrically conductive layers EL2 are formed as thick film bodies thicker than the electrically conductive layers EL1.

Then, contact holes are formed which penetrate through the SiOx film 8 from the upper surface of SiOx film 8 and reach the corresponding electrically conductive layers EL2. Next, a contact holes are filled with, for example, tungsten, and thus contacts CC are formed (FIG. 2L).

As explained above, the SiN films 2 remain on the upper surface, which is the SiN layers N, of each step of the stacked body SK, when the SiOx film 8 is formed to cover the stacked body SK of stair shape in the semiconductor device manufacturing method according to this embodiment. Because the SiN films 2 are also removed when the SiN layers N are removed after the SiOx film 8 is formed, the spaces SP2 are formed which have a higher height than the spaces SP1, which are formed by removing the SiN layers N. Because the spaces SP2 are filled with tungsten and thus the electrically conductive layers EL2 are formed, the electrically conductive layers EL2 are thicker than electrically conductive layers EL1 obtained by filling the spaces SP1 with tungsten. Then, the contacts CC are formed to the corresponding electrically conductive layers EL2.

If there are no SiN films 2 on the SiN layers N, electrically conductive layers of the same thickness as the electrically conductive layers EL1 are formed on the upper surface of each step of the stacked body SK. Although electrically conductive layers can generally function as etch stopper layers when the contact holes are formed, if the electrically conductive layers exposed as bottom surfaces of the contact holes are exposed to an etching environment for a relatively long time, the electrically conductive layers are also etched and then become thinner. In this case, the contact holes may penetrate through the electrically conductive layers, and thus a short circuit may occur between two vertically adjacent electrically conductive layers after the contacts are formed.

However, according to the semiconductor device manufacturing method of this embodiment, the electrically conductive layers ES2 with which the contacts are in contact can be thicker than the electrically conductive layers EL1, which may easily avoid that the contact holes from penetrating through the electrically conductive layers EL2.

By the way, in order to thicken the electrically conductive layers in contact with the contacts, it is also conceivable that the SiN layers N in the stacked body SK may be thickened. Namely, if the SiN layers N are thickened, the electrically conductive layers formed by filling tungsten thereinto can be thicker. However, in this case, a period of time required to form the stacked body SK tends to be longer, and a processing amount may be increased in processes for forming memory holes for memory cells, or the stair shape of the stacked body SK, which may lead to increased difficulties of processing.

On the other hand, according to the semiconductor device manufacturing method of this embodiment, because the electrically conductive layers EL2 in contact with the contacts CC can be thickened without thickening the electrically conductive layers EL1, a period of time required to form the stacked body SK can be prevented from being longer. Additionally, a processing amount in processes for forming memory holes for memory cells, the stair shape of the stacked body SK, and the like can be prevented from being increased; and increased difficulties of processing can be prevented.

Additionally, in the semiconductor device manufacturing method according to the embodiment, the template 10 is pressed onto the resist film 4 which is formed to cover the SiN film 2, and thus the resist film 4A (FIG. 1E) is obtained. When the resist film 4A is shrunk, the SiN film 2 becomes exposed on the side face of each step of the stacked body SK. This shrinkage is made, for example, by ashing. Because the SiN film 2 has tolerance to ashing, the SiN film 2 can have the same thickness as an as-depo thickness. Therefore, a width of the groove 6 formed by removing the SiN film 2 on the side face can be determined by a thickness of the SiN film 2. Because a thickness of the SiN film 2 is reproducible to relatively a higher degree, variations in a width of the groove 6 are also reducible.

The groove 6 is filled with SiOx at the time when the SiOx film 8, and turned to be a separating portion (referred to as a separating portion 6, when necessary, in the following) that separates the electrically conductive layer EL2 and the electrically conductive layer EL1 located one above the electrically conductive layer EL1 that is continuous with the electrically conductive layer EL2 concerned, as illustrated by an arrow G in FIG. 2K. The separating portion 6 contributes to reduction of the leakage current between the electrically conductive layer EL2 and the electrically conductive layer EL1 located one above the electrically conductive layer EL1 that is continuous with the electrically conductive layer EL2 concerned. Therefore, when variations in a width of the separating portion 6 are reduced, the leakage current can be reduced with a high reproducibility. Additionally, the trench T is formed at the bottom of the groove 6, and the trench T is filled with SiOx. With this, the trench T also contributes to reduction of the leakage current.

Incidentally, in order to reduce an above-mentioned leakage current, it is also conceivable that an inclined electrically conductive layer is formed on the upper surface of a step in substitution for electrically conductive layer EL2, the inclined electrically conductive layer being thinner toward the side face of the adjacently upper step. Because the inclined electrically conductive layer is thinner in a vicinity of the side face of the adjacent upper step, the inclined electrically conductive layer can be separated away from an electrically conductive layer that is one-step above an electrically conductive layer continuous with the inclined electrically conductive layers. However, in order to obtain such an inclined electrically conductive layer, it is necessary to deposit a SiN film that becomes thinner toward the side face of the adjacent upper step. However, it is not necessarily easy to control deposition of such a SiN film. For example, the SiN film may become too thin, which makes the resultant electrically conductive layer to be thinner, or the SiN film become too thick, which may cause leakage current in the end.

According to the semiconductor device manufacturing method according to the embodiment, a width of the groove 6 (and the trench T) can be controlled by a thickness of the SiN film 2 deposited on the side face of each step of the stacked body SK. With this, the electrically conductive layer EL2 is separated away from the electrically conductive layer EL1 and the electrically conductive layer EL1 that is one-step above the electrically conductive layer EL1 continuing the electrically conductive layer EL2, according to which a leakage current therebetween can be reduced. Additionally, because the electrically conductive layer EL2 can be uniform in thickness, even when positions of contact holes may vary, penetration of the contact holes through the electrically conductive layer EL2 can be prevented.

Modification 1

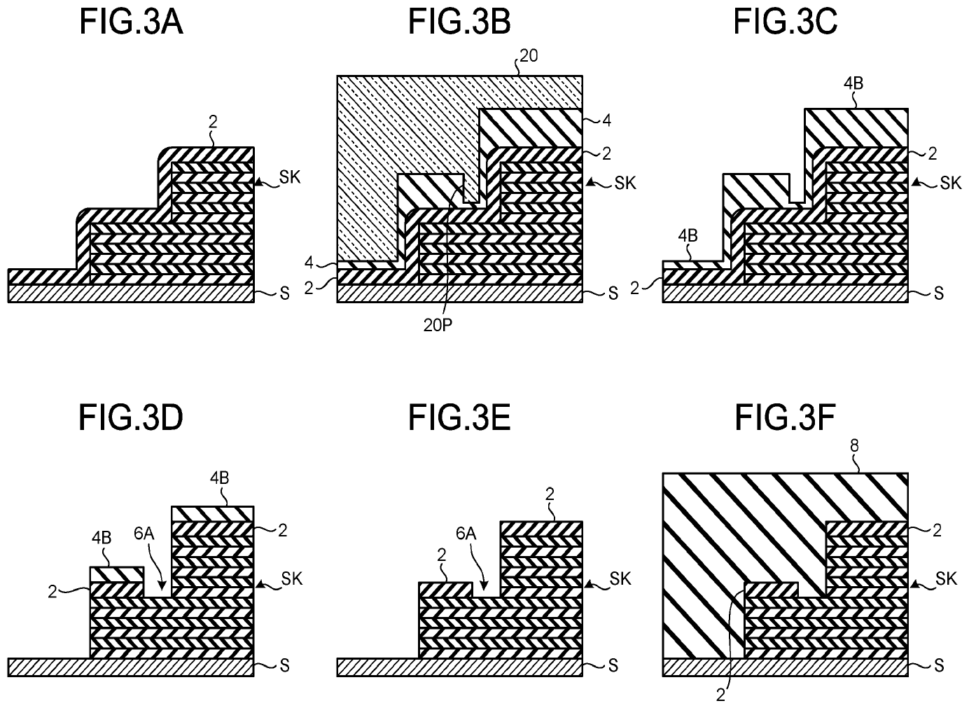

Referring now to FIGS. 3A through 3F, explanation is made on a semiconductor device manufacturing method according to modification 1 of the embodiment. The modification 1 is different in that a shape of a template used is different but is the same or similar to the above-described embodiment in other items. In the following, explanation focuses mainly on difference.

Referring to FIG. 3A, the SiN film 2 that covers a side face and an upper surface of each step of the stacked body SK of stair shape is formed. This SiN film 2 has been formed in such a manner as explained referring to FIG. 1A through FIG. 1C. The resist film 4 is applied to cover the SiN film 2, and a template 20 is pressed onto this resist film 4, as illustrated in FIG. 3B. Here, a protrusion 20P is formed in the template 20. The protrusion 20P is provided to correspond to a position closer to a side face of an adjacent above step than a side face of a step concerned. In other words, the protrusion 20P is provided to correspond to a position in a proximity of the SiN film 2 formed on the side face of the adjacent upper step standing up from the upper surface of the step concerned. When UV light is irradiated through the template 20 to the resist film 4 while the template 20 is pressed onto the resist film 4, the resist film 4 is hardened. With this, a resist film 4B (a resist pattern) is provided, as illustrated in FIG. 3C.

Then, an ashing process is performed on the resist film 4B, for example, in such a manner as explained referring to FIG. 1F, and thus the resist film 4B is isotropically shrunk. With this, while the resist film 4B remains on the upper surface of each step, the resist film 4B on the upper surface of the substrate S and the side face of each step is removed, and thus the SiN film 2 is exposed on the side face of each step. Next, the SiN films 2 are removed, for example, by wet etching (FIG. 3D). Here, a groove 6A is formed between resist film 4B remaining on the upper surface of each step and the side face of the step adjacent to each step. This groove 6A has a width of a sum of a thickness (width) of the SiN film 2 deposited on the side face of each step of the stacked body SK and a width of the protrusion 20P of the template 20. Namely, the groove 6A of modification 1 is wider by the width of the protrusion 20P of the template 20 compared with a width of the groove 6 formed by the semiconductor device manufacturing method according to the above-described embodiment.

Incidentally, the SiN layer N is exposed in a bottom of the groove 6A. This SiN layer N becomes slightly dented from an upper surface thereof, which result from removal of the SiN film 2. Namely, the SiN film 2 is removed under control of, for example, an etching time so that the SiN layer N is not isotropically removed and the trench T is formed in the SiN layer N.

Then, the resist film 4B remaining on each step of the stacked body SK is removed (FIG. 3E), and the SiOx film 8 is formed to cover the stacked body SK (FIG. 3F).

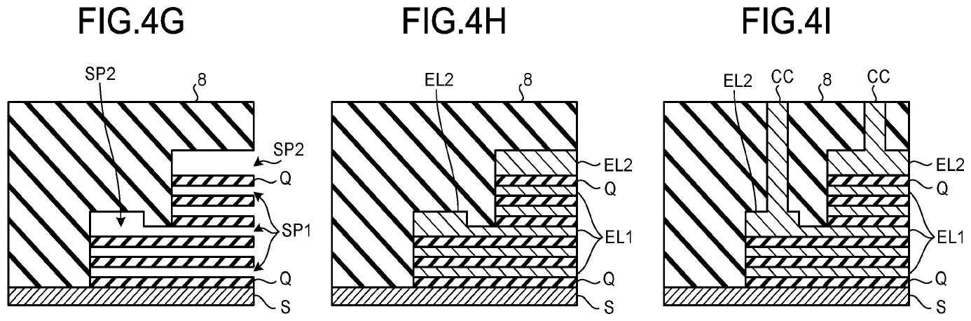

Subsequently, as illustrated in FIG. 4G, the SiN layers N are removed through through-holes or slits (not illustrated) formed in a central portion of the stacked body SK so as to penetrate through the stacked body SK, and thus spaces SP1 are formed. At this time, the SiN film 2 remaining on the upper surface of each step is also removed. Therefore, spaces SP2 having a height L2 higher than a height L1 of space SP1 are formed in the upper part of each step.

Next, the spaces SP1 and SP2 are filled with, for example, metal such as tungsten (W), by, for example, an atomic layer deposition (ALD) method and the like (FIG. 4H). With this, electrically conductive layers EL2 corresponding to the spaces SP1 and the electrically conductive layers EL1 corresponding to the spaces SP2 are obtained. Here, a thickness of electrically conductive layer EL2 is approximately equal to a height L2 of the space SP2, and is greater than a thickness of the electrically conductive height L1 of space SP1 and approximately equal electrically conductive layer EL1.

Next, contact holes are formed which penetrates through the SiOx film 8 from the upper surface thereof and reaches the electrically conductive layers EL2. Then, the contact holes are filled with, for example, tungsten, and thus contacts CC are formed (FIG. 4I).

As explained above, because the electrically conductive layers EL2 thicker than the electrically conductive layers EL1 can be formed on the upper surface of each step in the semiconductor device manufacturing method according to modification 1, effects exerted by the semiconductor device manufacturing method according to the embodiment is also exerted by the semiconductor device manufacturing method according to modification 1.

Additionally, according to the semiconductor device manufacturing method of modification 1, a width of the groove 6A is greater than a thickness of the SiN film 2 deposited on the side face of each step, due to the protrusion 20P provided in the template 20. Therefore, the electrically conductive layer EL2 is fully separated from the electrically conductive layer EL1 one-step above the electrically conductive layer EL1 continuing the electrically conductive layer EL2, according to which leakage current therebetween is further reduced.

Modification 2

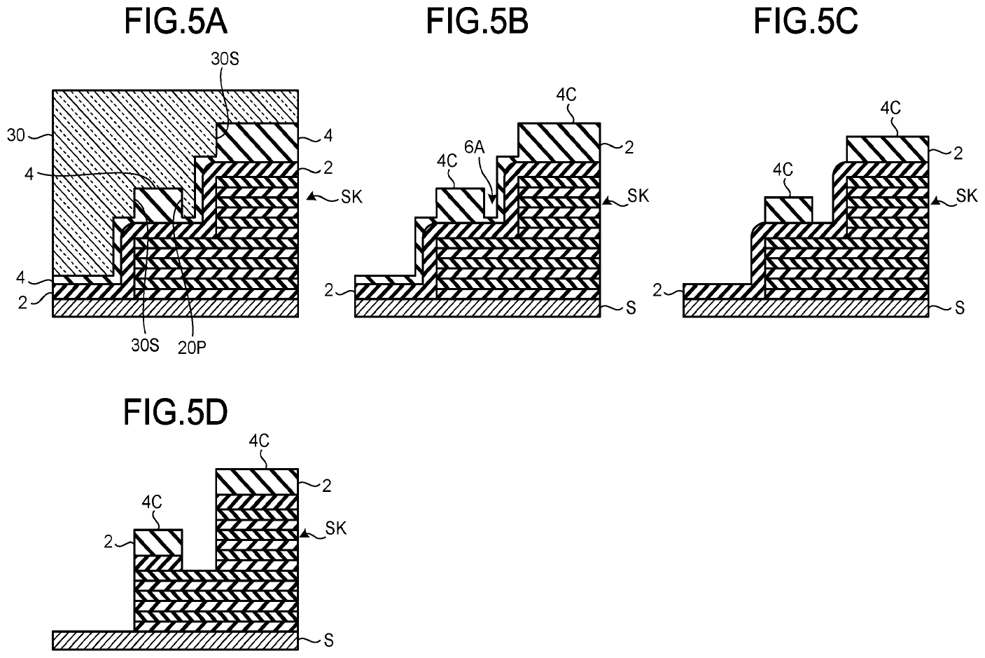

Referring now to FIGS. 5A through 5D, explanation is made on a semiconductor device manufacturing method according to modification 2 of the embodiment. In the following, explanation focuses on difference.

Referring to FIG. 5A, a template 30 is pressed onto the resist film 4 formed on the SiN film 2. This template 30 has a stepped portion 30S in addition to the protrusion 20P. When the template 30 was pressed onto the resist film 4, the stepped portion 30S is located at a position corresponding to the SiN film 2 deposited on the side face of each step of the stacked body SK. Additionally, a thickness of the stepped portion 30S is approximately equal to a thickness of the SiN film 2 deposited on the side face of each step of the stacked body SK.

When UV light is irradiated on the resist film 4 through the template 30 while the template 30 is pressed onto the resist film 4, a resist film 4C (a resist pattern) is obtained, as illustrated in FIG. 5B. Then, the resist film 4C is isotropically shrunk, and a resist remaining on the side face of each step of the stacked body SK and the upper surface of the substrate S is removed (FIG. 5C). With this, the SiN film 2 is exposed on the side face of each step of the stacked body SK, as illustrated in FIG. 5D.

Then, the same processes are performed which are the same as those explained referring to FIG. 3D through FIG. 4I, and thus the contacts are formed.

According to the semiconductor device manufacturing method of modification 2, because the template 30 has the stepped portion 30S, a width of the resist film 4C formed by the template 30 may be reduced. Therefore, a period of time required to shrink the resist film 4C can be shortened.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a stacked body including first films and second films that are stacked alternatively one on another, the stacked body having a stair shape at end portions thereof;
a thick film portion thicker than the second films within the stacked body and provided on an upper surface of a first step of the stair shape;
a separating portion provided on a side face between the first step and a second step one-step above the first step, the separating portion separating the thick film portion from the side surface;
a third film provided to cover the stacked body and the thick film portion; and
an electrically conductive column portion penetrating through the third film to be in contact with the thick film portion.

2. The semiconductor device according to claim 1, wherein the thick film portion has a uniform thickness.

3. The semiconductor device according to claim 1, wherein the first films are electrically insulating films.

4. The semiconductor device according to claim 1, wherein the second films and the thick film portion are formed of electrically conductive material.

5. The semiconductor device according to claim 1, wherein the electrically conductive material is tungsten.

6. The semiconductor device according to claim 1, wherein a dented portion is formed in the thick film portion by a lower end portion of the separating portion.

7. A semiconductor device manufacturing method comprising:
forming a stacked body by stacking first films and second films alternatively one on another;
processing an end portion of the stacked body into a stair shape so that the second films are exposed as an upper surface of each step of the stair shape;
forming a third film so that the stacked body having the stair shape at the end portion is covered by the third film;
pressing a template on a resist film formed on the third film so that a mask layer is formed on the third film on the upper surface of the stair shape;
removing the third film on a side face of each step of the stair shape, using the mask layer;
forming a fourth film so that the stacked body having the third film on the upper surface of the stair shape;
removing the second films and the third film remained on the upper surface to form a hollow space; and
filling the hollow space with an electrically conductive material.

8. The semiconductor device manufacturing method according to claim 7, wherein
the forming the mask layer includes
forming a resist pattern by illuminating the resist film with ultraviolet light through the templated while the templated is pressed on the resist film; and
shrinking the resist pattern.

9. The semiconductor device manufacturing method according to claim 7, wherein
the template includes
a stepped recess portion that corresponds to the stair shape; and
a protrusive portion on an end portion of each step of the stepped recess portion.

10. The semiconductor device manufacturing method according to claim 9, wherein the protrusive portion is to be positioned the side surface when the template is pressed on the resist film.

11. The semiconductor device manufacturing method according to claim 7, wherein the first films are electrically insulating film.

12. The semiconductor device manufacturing method according to claim 7, wherein the electrically conductive material is tungsten.
